(19) United States
(12) Patent Application Publication
(10) Pub. No.: US 2024/0006525 A1
(43) Pub. Date: Jan. 4, 2024

(54) METHOD FOR MANUFACTURING HIGH ELECTRON MOBILITY TRANSISTOR DEVICE

(71) Applicant: United Microelectronics Corp., Hsinchu (TW)

(72) Inventors: Yuan Yu Chung, Tainan City (TW); Bo-Yu Chen, Yilan County (TW); You-Jia Chang, Taoyuan City (TW); Lung-En Kuo, Tainan City (TW); Kun-Yuan Liao, Hsinchu City (TW); Chun-Lung Chen, Tainan City (TW)

(73) Assignee: United Microelectronics Corp., Hsinchu (TW)

(21) Appl. No.: 17/870,746

(22) Filed: Jul. 21, 2022

(30) Foreign Application Priority Data
Jun. 30, 2022 (TW) 111124463

(51) Int. Cl. H01L 29/778; H01L 29/66; H01L 29/20; H01L 29/205

(52) U.S. Cl. CPC H01L 29/7786; H01L 29/66462; H01L 29/2003; H01L 29/205

(57) ABSTRACT

A method for manufacturing a high electron mobility transistor device includes providing a substrate. A channel material, a barrier material, a polarization adjustment material and a conductive material are formed on the substrate. A hard mask layer is formed on the conductive material. The conductive material is patterned to form a conductive layer by using the hard mask layer as a mask. A plurality of protection layers is formed on sidewalls of the hard mask layer and the conductive layer. The polarization adjustment material is patterned to form a polarization adjustment layer by using the plurality of protection layers and the hard mask as masks. The plurality of protection layers is removed. A portion of the conductive layer is laterally removed to form a first gate conductive layer.

### CROSS-REFERENCE TO RELATED APPLICATION

This application claims the priority benefit of Taiwan application serial no. 111124463, filed on Jun. 30, 2022. The entirety of the above-mentioned patent application is hereby incorporated by reference herein and made a part of this specification.

### BACKGROUND

### Field of the Disclosure

The present disclosure relates to a method of manufacturing a semiconductor device, and more particularly, to a method of manufacturing a high electron mobility transistor device.

### Description of Related Art

In semiconductor technology, group III-V semiconductor compounds may be used to form various integrated circuit components, such as high power field effect transistors, high frequency transistors or high electron mobility transistors (HEMT). HEMT is a field effect transistor with a two-dimensional electron gas (2DEG) layer that is adjacent to the junction between two materials with different energy gaps (i.e., heterojunction). Since HEMT does not use a doped region as a carrier channel of the transistor, but uses the 2DEG layer as the carrier channel of the transistor, compared with the conventional MOSFET (Metal Oxide Half Field Effect Transistor), HEMT has various appealing characteristics such as high electron mobility and the capability to transmit signals at high frequencies. However, the control of the profile and size of the gate of the HEMT is very important. Improper control may cause leakage current or lead to abnormal electrical connection.

### SUMMARY OF THE DISCLOSURE

The present disclosure provides a method for manufacturing a high electron mobility transistor device capable of controlling the profile and size of the gate to avoid leakage current or abnormal electrical connection.

In an embodiment of the disclosure, a method for manufacturing a high electron mobility transistor device includes the following steps: providing a substrate, a channel material, a barrier material, a polarization adjustment material and a conductive material are formed on the substrate; forming a hard mask layer on the conductive material; pattering the conductive material to form a conductive layer by using the hard mask layer as a mask; forming a plurality of protection layers on sidewalls of the hard mask layer and the conductive layer; patterning the polarization adjustment material to form a polarization adjustment layer by using the plurality of protection layers and the hard mask as masks; removing the plurality of protection layers; laterally removing a portion of the conductive layer to form a first gate conductive layer.

In the embodiment of the present disclosure, the profile and size of the first gate conductive layer may be controlled by the setting of the protection layer, so as to avoid leakage current or prevent abnormal electrical connection from being generated between the second gate conductive layer and the polarization adjustment layer formed subsequently.

### BRIEF DESCRIPTION OF THE DRAWINGS

FIG. 1A to FIG. 1J are schematic cross-sectional views of a method for manufacturing a high electron mobility transistor device according to an embodiment of the present disclosure.

### DESCRIPTION OF EMBODIMENTS

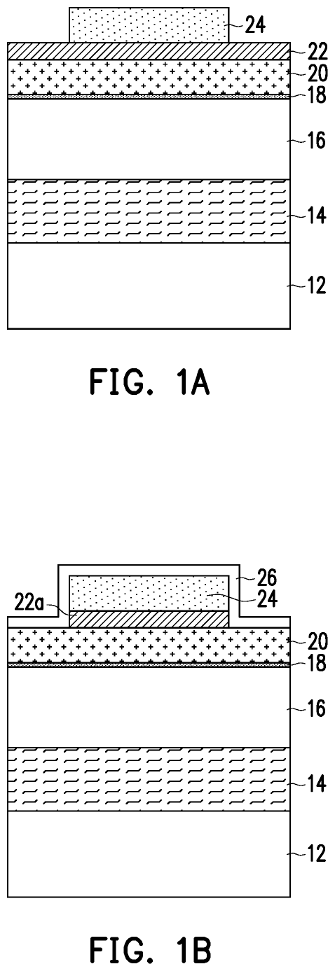

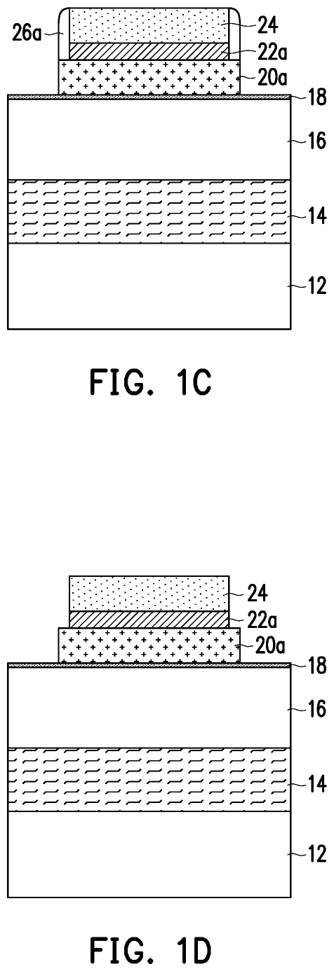

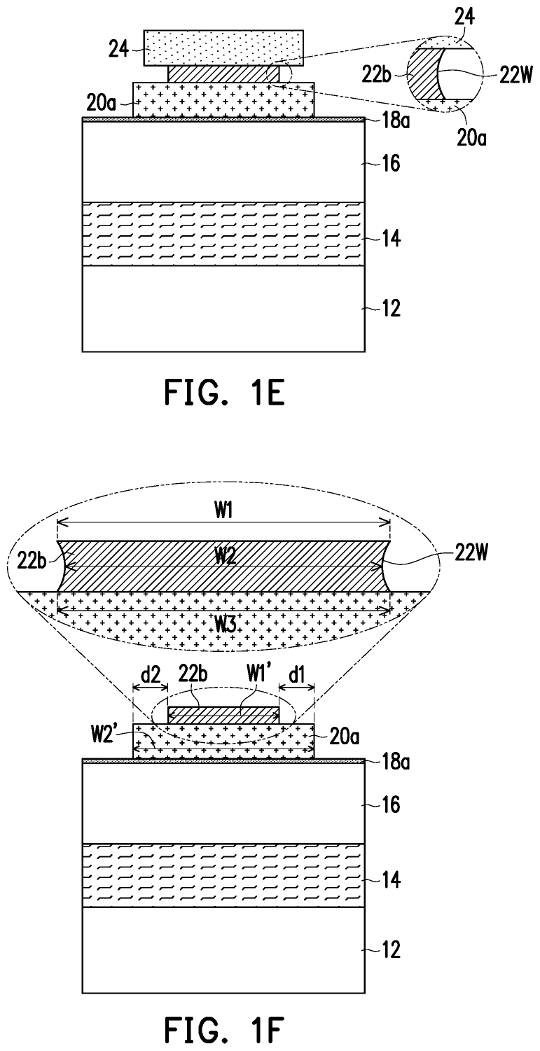

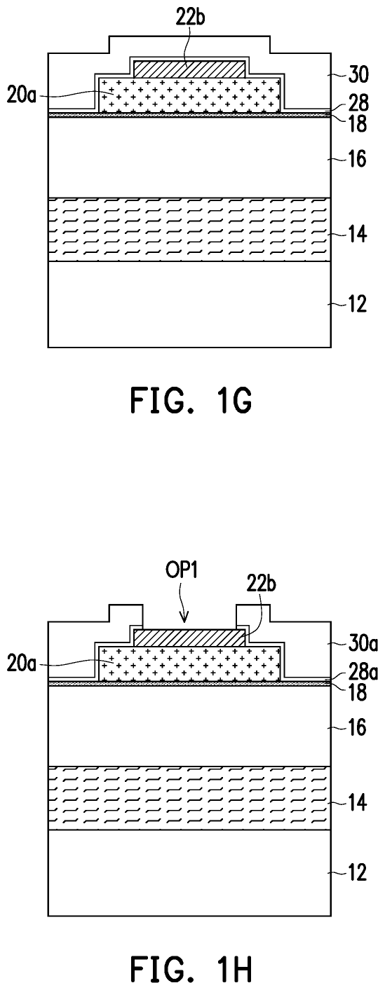

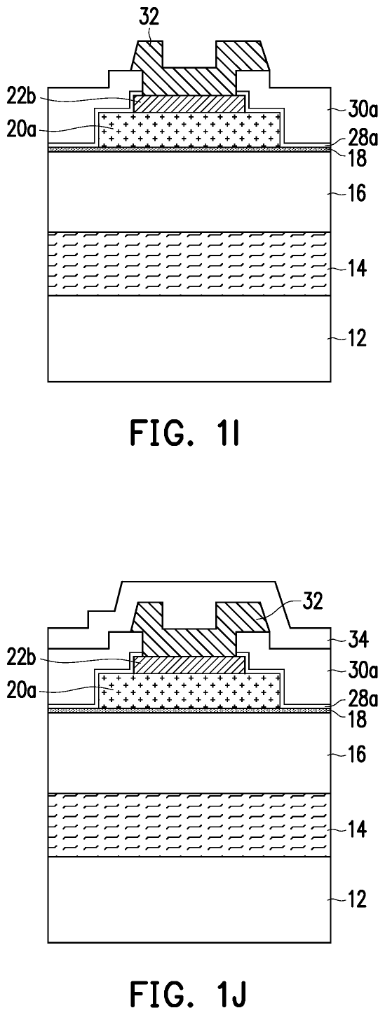

FIG. 1A to FIG. 1J are schematic cross-sectional views of a method for manufacturing a high electron mobility transistor device according to an embodiment of the present disclosure.

Referring to FIG. 1A, a substrate 12 is provided first. The substrate 12 may be a monocrystalline substrate. The material of the substrate 12 includes semiconductors, such as silicon, silicon carbide or aluminum oxide (or sapphire). The substrate 12 may be a single-layer substrate, a multi-layer substrate, a gradient substrate, or a combination thereof. According to other embodiments of the present disclosure, the substrate 12 may be a silicon-on-insulator (SOI) substrate. In some embodiments, the substrate 12 includes (111) monocrystalline silicon.

Then, a buffer material 14 is formed on the substrate 12. The buffer material 14 may reduce stress between the substrate 12 and the subsequently formed channel material 16. In an embodiment, the buffer material 14 and operating steps are optional and may be omitted. The buffer material 14 may be a single layer or multiple layers. The buffer material 14 is, for example, a doped III-V semiconductor, such as carbon-doped gallium nitride (C doped-GaN). In some embodiments, the dopant (e.g., carbon) of the buffer material 14 may be formed in situ during the process of forming the gallium nitride. The buffer material 14 may be formed through an epitaxial growth process. In some embodiments, the buffer material 14 may be formed by using a molecular-beam epitaxy (MBE) process, a metal organic chemical vapor deposition (MOCVD) process, a chemical vapor deposition (CVD) process, or a hydride vapor phase epitaxy (HVPE) process.

Subsequently, a channel material 16 is formed on the buffer material 14. In some embodiments not including the buffer material 14, the channel material 16 is formed directly on the substrate 12. The channel material 16 is, for example, an undoped III-V semiconductor, such as undoped gallium nitride (undoped-GaN). The channel material 16 is not doped during the forming process, but the resulting undoped III-V semiconductor may have a small amount of impurities due to residual substances in the processing machine. The channel material 16 may be formed by using an epitaxial growth process. In some embodiments, the channel material 16 may be formed by using an MBE process, a MOCVD process, a CVD process, or a HVPE process.

Next, a barrier material 18 is formed on the channel material 16. The heterojunction of the two-dimensional electron gas (2DEG) is adjacent to the interface between the barrier material 18 and the channel material 16 in the channel material 16. The barrier material 18 may be a single layer or multiple layers. The barrier material 18 is, for example, a group III-V semiconductor, such as aluminum gallium nitride (AlxGa1-xN), and 0>x>1, and x is between 16 to 30%. The barrier material 18 may be formed by using an epitaxial growth process. In some embodiments, the channel material 16 may be formed by using MBE, MOCVD process, CVD process, and HVPE process.

Afterwards, a polarization adjustment material 20 is formed on the barrier material 18. The polarization adjustment material 20 may adjust the dipole content in the barrier material 18 to cause changes in the concentration of 2-DEG 20. Typically, the polarization adjustment material 20 is formed for enhancement-mode (normally off) AlGaN/GaN HEMTs, whereas a polarization adjustment layer is not required in depletion-mode (normally on) AlGaN/GaN HEMTs. The polarization adjustment material 20 is, for example, a P-type doped III-V semiconductor, such as P-type doped gallium nitride (P-typed-GaN). The P-type dopant is, for example, boron or boron trifluoride. In some embodiments, the P-type dopant of the polarization adjustment material 20 may be formed in situ during the process of forming the gallium nitride. The polarization adjustment material 20 may be formed into a P-type doped epitaxial layer by using an epitaxial growth process. The epitaxial growth process is, for example, MBE process, MOCVD process, CVD process, and HVPE process. In some embodiments, the polarization adjustment material 20, the barrier material 18, the channel material 16, and the buffer material 14 may be formed in situ.

Next, a conductive material 22 is formed on the polarization adjustment material 20. The conductive material 22 includes metal. The conductive material 22 is, for example, gold, silver, platinum, titanium, aluminum, tungsten, palladium or a combination thereof. The conductive material 22 may be a single layer or multiple layers. In some embodiments, the conductive material includes titanium nitride (TiN). The conductive material 22 may be formed by using, for example, an electroplating process, a sputtering process, a resistance heating evaporation process, an electron beam evaporation process, a physical vapor deposition (PVD) process, and a chemical vapor deposition (CVD) process.

Afterwards, a hard mask layer 24 is formed on the conductive material 22. The hard mask layer 24 includes an insulating material such as silicon nitride. The hard mask layer 24 may be formed by patterning the insulating material through lithography and etching processes. The thickness of the hard mask layer 24 is, for example, 80 nm to 120 nm.

Next, referring to FIG. 1B, the hard mask layer 24 is used as an etching mask to perform an etching process, such as an anisotropic etching process, is performed to pattern the conductive material 22 to form the conductive layer 22a.

Thereafter, a protection material 26 is formed on the hard mask layer 24 and the polarization adjustment material 20. The protection material 26 covers the polarization adjustment material 20 and the top surface of the hard mask layer 24 and the sidewalls of the hard mask layer 24 and the conductive layer 22a. The protection material 26 is a different material than the hard mask layer 24. The protection material 26 includes an insulating material, such as silicon oxide, but not limited thereto. The forming method of the protection material 26 is, for example, a plasma-enhanced chemical vapor deposition (PECVD) method or an atomic layer deposition (ALD) method. The gas adopted in the plasma enhanced chemical vapor deposition method is, for example, tetraethoxysiloxane (TEOS). The thickness of the protection material 26 is, for example, between 20 nm and 40 nm.

Thereafter, referring to FIG. 1C, a removal process, such as an anisotropic etching process, is performed to remove the polarization adjustment material 20 and the protection material 26 on the top surface of the hard mask layer 24. The protection material 26 remaining on the sidewalls of the hard mask layer 24 and the conductive layer 22a is formed into a protection layer 26a. The width of the protection layer 26a is, for example, between 20 nm and 40 nm.

Referring to FIG. 1C, the protection layer 26a and the hard mask layer 24 are used as masks to perform an etching process to pattern the polarization adjustment material 20, thereby forming the polarization adjustment layer 20a. The etching process is, for example, a dry etching process, and the etching gas includes, for example, chlorine gas. During the etching process, since the protective layer 26a covering the sidewall of the conductive layer 22a may protect the conductive layer 22a and prevent the chlorine gas from contacting the conductive layer 22a, the conductive layer 22a may maintain the original size, thus preventing the conductive layer 22a on the entire substrate 10 from being etched laterally during the etching process, thereby avoiding the problem of uneven etching.

Referring to FIG. 1D, the protection layer 26a is removed to expose the sidewalls of the hard mask layer 24 and the conductive layer 22a. The method of removing the protection layer 26a may adopt an etching process. The etching process may be an isotropic etching process, such as a wet etching process. In some embodiments, the protection layer 26a includes silicon oxide, and the etchant used in the etching process is, for example, diluted hydrofluoric acid. In the process of removing the protection layer 26a, since the material of the hard mask layer 24 is different from the material of the protection layer 26a, the conductive layer 22a underneath may be protected from being damaged by etching.

Referring to FIG. 1E, a lateral etching process is performed to laterally remove a portion of the conductive layer 22a to form a gate conductive layer 22b. In some embodiments, the gate conductive layer 22b may also be referred to as a gate interlayer, a lower gate conductive layer or a first gate conductive layer. The lateral etching process includes an isotropic etching process, such as a wet etching process. The lateral etching process may be performed by selecting an etchant with a high etch selectivity ratio between the conductive layer 22a and the polarization adjustment layer 20a. This etching process may well control the amount of the conductive layer 22a that is laterally etched, so that the formed gate conductive layer 22b has a desired size and profile. In some embodiments, the conductive layer 22a includes TiN, and the lateral etching process includes a wet etching process. For example, the treatment is performed by using SPM solution at 90° C. containing sulfuric acid (H₂SO₄), hydrogen peroxide (H₂O₂) and water first, and SC1 solution at 65° C. containing ammonium hydroxide (NH₄OH), hydrogen peroxide (H₂O₂) and water is used afterwards for treatment. In some embodiments, the etching selectivity ratio of the conductive layer 22a to the polarization adjustment layer 20a is greater than 100, for example. In other embodiments, the etching selectivity ratio of the conductive layer 22a to the polarization adjustment layer 20a is greater than 500, for example. In still other embodiments, the etching selectivity ratio of the conductive layer 22a to the polarization adjustment layer 20a is greater than 1000, for example. In some embodiments, due to the wet etching process, the etching selectivity of the conductive layer 22a to the polarization adjustment layer 20a has a relatively high etching selectivity ratio, it is possible to improve the etching uniformity of the conductive layer 22a on the entire substrate 12.

Referring to FIG. 1F, the hard mask layer 24 is removed to expose the top surface of the gate conductive layer 22b. In some embodiments, the formed gate conductive layer 22b may have a curved sidewall 22w. In other words, the middle width W2 of the gate conductive layer 22b is smaller than the upper width W1 of the gate conductive layer 22b and smaller than the lower width W3 of the gate conductive layer 22b. However, the embodiments of the present disclosure are not limited thereto. In other embodiments, the gate conductive layer 22b may be formed with a vertical sidewall (not shown).

By using the method in the embodiment of the present disclosure, an optimized width of the gate conductive layer 22b and an optimized width of the polarization adjustment layer 20a may be obtained. In the embodiment of the present disclosure, the width of the gate conductive layer 22b is smaller than the width of the polarization adjustment layer 20a.

The average width W1′ of the gate conductive layer 22b is, for example, 1700 nm to 1800 nm, and the average width W2′ of the polarization adjustment layer 20a is, for example, between 1900 nm and 2100 nm. The ratio of the average width W1′ of the gate conductive layer 22b to the average width W2′ of the polarization adjustment layer 20a is, for example, 1:1.05 to 1:1.25. The one-side width differences d1 and d2 of the gate conductive layer 22b and the polarization adjustment layer 20a are, for example, between 50 nm and 200 nm. In some embodiments, the polarization adjustment layer protrudes from the sidewalls on both sides of the gate conductive layer 22b, and steps are formed on both sides of the gate conductive layer 22b and the polarization adjustment layer 20a. The one-side width differences d1 and d2 of the gate conductive layer 22b and the polarization adjustment layer 20a may be substantially equal to or slightly different from each other.

Next, referring to FIG. 1G an intermediate material 28 and a dielectric material are formed on the gate conductive layer 22b, the polarization adjustment layer 20a, and the barrier material 18. The intermediate material 28 is of a different material than the dielectric material 30. The intermediate material 28 is, for example, silicon nitride, aluminum oxide, or a combination thereof, and is formed by, for example, an atomic layer deposition (ALD) method. The dielectric material 30 is, for example, silicon oxide, and is formed by, for example, a plasma-enhanced chemical vapor deposition (PECVD) method. The gas used in the PECVD method is, for example, tetraethoxysiloxane (TEOS).

Thereafter, referring to FIG. 1H, a patterning process is performed on the dielectric material 30 and the intermediate material 28 by lithography and etching processes to form the dielectric layer 30a and the intermediate layer 28a. The dielectric layer 30a and the intermediate layer 28a have openings OP1, exposing the gate conductive layer 22b. During the etching process, the dielectric material 30 may be etched first by using the intermediate material 28 as an etch stop layer. After that, the etching process is continued to expose the gate conductive layer 22b after removing the intermediate material 28. Since the size and shape of the gate conductive layer 22b are properly controlled, even if misalignment occurs during the forming process of the opening OP1, the opening OP1 may still be formed directly above the gate conductive layer 22b without shifting and causing polarization adjustment layer 20a to be exposed.

Thereafter, referring to FIG. 1I, a gate conductive layer 32 is formed on the opening OP1 and the dielectric layer 30a. The gate conductive layer 32 is landed on the gate conductive layer 22b, and forms a gate together with the gate conductive layer 22b. In some embodiments, the gate conductive layer 32 may also be referred to as an upper gate conductive layer, a second gate conductive layer or a gate contact. The method for forming the gate conductive layer 32 is, for example, forming a metal material on the opening OP1 and the dielectric layer 30a, and then patterning the metal material through a lithography and etching process. The gate conductive layer 32 may be a single layer or a multi-layer. The material of the gate conductive layer 32 includes Ti, TiN, AlCu or a combination thereof. In some embodiments, the gate conductive layer 32 is, for example, a TiN/Ti/AlCu/Ti/TiN composite layer.

Then, referring to FIG. 1J, a gate capping material 34 is formed on the gate conductive layer 32 and the dielectric layer 30a. The gate cap material 34 is, for example, silicon oxide, silicon nitride, silicon oxynitride, carbon-doped silicon oxide, carbon-doped silicon nitride, carbon-doped silicon oxynitride, zinc oxide, zirconium oxide, hafnium oxide, titanium oxide, or another suitable material, and formed by a PECVD method, for example. After that, a process such as forming source/drain contact is performed. The source/drain contact passes through the gate cap material 34 and the dielectric layer 30a and is electrically connected to channel material 16. The source/drain contact includes a conductive material such as gold, silver, platinum, titanium, aluminum, tungsten, copper, palladium, or combinations thereof. The conductive material includes ohmic contact metals.

To sum up, the present disclosure may control the profile and size of the lower gate conductive layer by setting the protection layer, so as to avoid leakage current, or to prevent the upper gate conductive layer from landing on the polarization adjustment layer, thereby avoiding abnormal connection.

What is claimed is:

1. A method for manufacturing a high electron mobility transistor device, comprising:
providing a substrate,
wherein a channel material, a barrier material, a polarization adjustment material and a conductive material are formed on the substrate;
forming a hard mask layer on the conductive material;
pattering the conductive material to form a conductive layer by using the hard mask layer as a mask;
forming a plurality of protection layers on sidewalls of the hard mask layer and the conductive layer;
patterning the polarization adjustment material to form a polarization adjustment layer by using the plurality of protection layers and the hard mask as the masks;
removing the plurality of protection layers; and
laterally removing a portion of the conductive layer to form a first gate conductive layer.

2. The method for manufacturing the high electron mobility transistor device according to claim 1, wherein the step of laterally removing the portion of the conductive layer comprises an isotropic etching process.

3. The method for manufacturing the high electron mobility transistor device according to claim 2, wherein the isotropic etching process comprise a wet etching method.

4. The method for manufacturing the high electron mobility transistor device according to claim 1, wherein the step of forming the plurality of protection layers comprises:
forming a protection material covering a top surface of the polarization adjustment material, and top surfaces and sidewalls of the hard mask layer and the conductive layer; and
performing an anisotropic etching process to remove a part of the protection material, thereby forming the plurality of protection layers.

5. The method for manufacturing the high electron mobility transistor device according to claim 1, wherein a ratio of a width of the first gate conductive layer to a width of the polarization adjustment layer is 1:1.05 to 1:1.25.

6. The method for manufacturing the high electron mobility transistor device according to claim 1, wherein a material of the plurality of protection layers is different from a material of the hard mask layer.

7. The method for manufacturing the high electron mobility transistor device according to claim 6, wherein the material of the plurality of protection layers comprises silicon oxide, and the material of the hard mask layer comprises silicon nitride.

8. The method for manufacturing the high electron mobility transistor device according to claim 1, wherein a sidewall of the first gate conductive layer is a curved surface.

9. The method for manufacturing the high electron mobility transistor device according to claim 8, wherein a middle width of the first gate conductive layer is smaller than an upper width of the first gate conductive layer and smaller than a lower width of the first gate conductive layer.

10. The method for manufacturing the high electron mobility transistor device according to claim 1, wherein the first gate conductive layer comprises TiN, and the polarization adjustment layer comprises p-type doped GaN.

11. The method for manufacturing the high electron mobility transistor device according to claim 1, further comprising removing the hard mask layer.

12. The method for manufacturing the high electron mobility transistor device according to claim 11, further comprising:
forming an intermediate material on the first gate conductive layer, the polarization adjustment layer and the barrier material;
forming a dielectric material on the intermediate material; and
patterning the dielectric material and the intermediate material to form a dielectric layer and an intermediate layer having openings; and
forming a second gate conductive layer on the dielectric layer and the intermediate layer and in the opening, wherein the second gate conductive layer is landed on the first gate conductive layer.

13. The method for manufacturing the high electron mobility transistor device according to claim 12, wherein the intermediate layer comprises aluminum oxide, and the dielectric layer comprises silicon oxide.
